(19) United States
(12) Patent Application Publication
(10) Pub. No.: US 2006/0039428 A1
(43) Pub. Date: Feb. 23, 2006

(54) Semiconductor laser device and manufacturing method therefor

(75) Inventor: Masaki Kondou, Hiroshima-Ken (JP)

Correspondence Address: MORRISON & FOERSTER LLP, 1650 TYSONS BOULEVARD, SUITE 300, MCLEAN, VA, 22102, US

(73) Assignee: SHARP KABUSHIKI KAISHA, Osaka-shi (JP)

(21) Appl. No.: 11/205,022

(22) Filed: Aug. 17, 2005

(30) Foreign Application Priority Data
Aug. 17, 2004 (JP) 2004-237705

(51) Int. Cl. H01S 5/00

(52) U.S. Cl. 372/43.01

(57) ABSTRACT

In a semiconductor laser device, a first cladding layer (2), a quantum well active layer (3), a second cladding layer (4), and an etching stopper layer (5) are sequentially stacked in this order on a substrate (1). On the etching stopper layer (5) is disposed a striped ridge portion (11) that is composed of a third cladding layer (14) and a contact layer (6). A p-side electrode (31) is provided on the ridge portion (11). Side faces of the ridge portion (11) except the contact layer (6) are covered with a dielectric film (21). The contact layer (6) has a layer thickness larger than a film thickness of a portion of the dielectric film (21) that is roughly parallel to the substrate (1)

This nonprovisional application claims priority under 35 U.S.C. §119(a) on Patent Application No. 2004-237705 filed in Japan on Aug. 17, 2005, the entire contents of which are hereby incorporated by reference.

### BACKGROUND OF THE INVENTION

The present invention relates to a semiconductor laser device and a manufacturing method therefor.

Conventionally, there has been known a ridge waveguide structure as a structure of semiconductor laser devices that are capable of effectively fulfilling current constriction and light confinement. In the ridge waveguide structure, a striped ridge portion is formed on a compound semiconductor layer on a semiconductor substrate, and a dielectric film (burying layer) is formed on both sides of the ridge portion. An upper portion of the ridge portion is formed of a contact layer. An energizing electrode, such as an ohmic electrode, for performing current injection into the ridge portion is connected to a flat top surface of the contact layer.

For the semiconductor laser device having such a ridge waveguide structure, it needs to be ensured that side faces of the ridge portion are covered with a dielectric film of a specified film thickness in terms of transverse mode control of laser oscillation, while the contact area between the contact layer and the energizing electrode needs to be increased to decrease electrical resistance between the contact layer and the energizing electrode in terms of low-current drive.

A conventional semiconductor laser device of the ridge waveguide type is described in Patent Document 1 (JP H06-77587 A).

FIG. 8 shows a schematic sectional view of the ridge waveguide type semiconductor laser device.

The semiconductor laser device has, on an n-GaAs substrate 111, an n-AlGaAs graded cladding layer 112, an n-AlGaAs first cladding layer 113, an n-AlGaAs graded cladding layer 114, an n-AlGaAs second cladding layer 115, an n-AlGaAs graded cladding layer 116, a GaAs/InGaAs strained quantum well active layer 117, an n-AlGaAs graded cladding layer 118, and a p-InGaP third cladding layer 119, which are stacked in this order.

On the p-InGaP third cladding layer 119 is disposed a striped ridge portion composed of a p-AlGaAs graded cladding layer 120, a p-AlGaAs fourth cladding layer 121, a p-AlGaAs graded cladding layer 122, and a p-GaAs contact layer 123.

A top face of the p-InGaP third cladding layer 119 and side faces of the ridge portion are covered with a SiO₂ insulating film 124. A p-side electrode 125 is provided on the p-GaAs contact layer 123 and the SiO₂ insulating film 124, while an n-side electrode 126 is provided on the backside of the n-GaAs substrate 111.

The SiO₂ insulating film 124 can be obtained by covering the p-InGaP third cladding layer 119 and the ridge portion entirely with SiO₂ and removing only a part of the SiO₂ placed on the p-GaAs contact layer 123, which is an upper portion of the ridge, through an exposure step and an etching step.

The exposure step and the etching step are performed taking a process margin into consideration in order to make sure that the SiO₂ portion on top of the p-GaAs contact layer 123 alone is removed. It follows that the SiO₂ insulating film 124, which is poorer in thermal conductivity than the semiconductor layers, covers both side portions of the p-GaAs contact layer 123. As a result, there are possibilities of occurrence of faulty high temperature operations or reliability deteriorations.

Further, since the SiO₂ insulating film 124 covers both the side portions of the p-GaAs contact layer 123, the contact area between the p-GaAs contact layer 123 and the p-side electrode 125 becomes smaller than the area of the top flat surface of the p-GaAs contact layer 123. As a result, the semiconductor laser device has a high electrical resistance.

Recently, as one characteristic, semiconductor laser devices have been required to have a fundamental transverse mode oscillation in which no higher-order mode is generated. To obtain the fundamental transverse mode oscillation with the semiconductor laser device of FIG. 8, there is a need for limiting the ridge width to 2 to 3 μm or less, and moreover limiting the width of the top face of the p-GaAs contact layer 123 also to 2 to 3 μm or less. Then, the contact area between the p-GaAs contact layer 123 and the p-side electrode 125 is further reduced, causing a problem of further increased electrical resistance of the semiconductor laser device.

A ridge waveguide type semiconductor laser device that can solve the above problem is described in Patent Document 2 (JP 2003-115632 A). This semiconductor laser device is manufactured in the following manner.

First, as shown in FIG. 9A, an n-InP cladding layer 202, an InGaAsP active layer 203, a p-InP cladding layer 204 and a p-InGaAs contact layer 205 are sequentially stacked in this order on an n-InP substrate 201. Thereafter, etching is done until after part of the p-InP cladding layer 204 is left, by which a ridge portion 217, recess portions 218A, 218B and terrace portions 219A, 219B are formed. A SiO₂ mask layer 207 is used as the etching mask for forming the ridge portion 217.

Next, as shown in FIG. 9B, after the SiO₂ mask layer 207 is removed, a SiO₂ insulator layer 208 is formed on the p-InP cladding layer 204 and the p-InGaAs contact layer 205, and further a top face of the insulator layer 208 is coated with a positive-type resist layer 209. In this process, resist viscosity and spin coating conditions are adjusted so that a layer thickness d1 of the resist layer 209 on the ridge portion 217 becomes thinner than a smallest resist layer thickness d3 of the resist layer 209 at the recess portions 218A, 218B.

Next, as shown in FIG. 9C, after an exposure step is performed by using an exposure mask 210 as a photomask, the resist layer 209 is removed by etching by the thickness d1, so that the insulator layer 208 on the p-InGaAs contact layer 205 is exposed.

Next, as shown in FIG. 9D, the insulator layer 208 on the ridge portion 217 is removed by etching, by which the top face of the p-InGaAs contact layer 205 is entirely exposed.

Next, as shown in FIG. 9E, the resist layer 209 is entirely removed, and a p-side electrode 212 is formed on the top face of the p-InGaAs contact layer 205, and thereafter a pad electrode 213 connecting to the p-side electrode 212 is formed.

Finally, after rear-face polishing of the n-InP substrate 201, an n-side electrode 214 is formed on the rear face of the n-InP substrate 201, as a result of which the multilayered structure of a ridge waveguide type semiconductor laser wafer is completed.

In such a manufacturing method, part of the insulator layer 208 is removed so that the top face of the p-InGaAs contact layer 205 is entirely exposed, and thereafter the p-side electrode 212 is formed. Therefore, the entire top face of the p-InGaAs contact layer 205 can be brought into contact with the p-side electrode 212. That is, the contact area between the p-InGaAs contact layer 205 and the p-side electrode 212 can be increased. Accordingly, the semiconductor laser device of Patent Document 2 can be made lower in electrical resistance than the semiconductor laser device of Patent Document 1.

In this connection, as shown in FIG. 10A, which is an enlarged schematic view of FIG. 9B, the resist layer thickness d1 of the resist layer 209 on the p-InGaAs contact layer 205 actually has variations within the wafer. Therefore, for removal of the entire resist layer 209 on the p-InGaAs contact layer 205 over the entire wafer, the exposure step and etching step should be performed such that the thickest resist layer 209 on the p-InGaAs contact layer 205 can be removed. That is, it is necessary to perform the exposure step and the etching step such that the resist layer 209 of the largest resist layer thickness d1ₘₐₓ on the p-InGaAs contact layer 205 is completely removed.

However, if the exposure step and etching step are performed in that way, as a result of excessive progress of etching, not only the top face of the insulator layer 208 but also side faces of the insulator layer 208 may be exposed in regions having the resist layer 209 of the minimum layer thickness d1min on the p-InGaAs contact layer 205, as shown in FIG. 10B.

Subsequently, as shown in FIG. 10C, the insulator layer 208 on the top face of the p-InGaAs contact layer 205 is etched, where the etching on the insulator layer 208 progresses not only from above but also from sides.

In this case, since corner portions of the insulator layer 208 are etched at higher etching rate, it becomes harder to control the time of etching. On this account, the p-InP cladding layer 204 may be partly exposed, as shown in FIG. 10D. In such a state, forming the p-side electrode 212 on the p-InGaAs contact layer 205 would cause the p-side electrode 212 to adhere to part of the p-InP cladding layer 204 so that Au (gold), which is a constituent of the p-side electrode 212, would diffuse into the p-InP cladding layer 204. This would give rise to an issue of deterioration in laser device characteristics.

In particular, with the p-InP cladding layer 204 containing P (phosphorus) as one of its constituent elements, in which Au is more likely to diffuse, Au would diffuse to the light-emitting region with an elapse of time, so that light absorption would increase in the Au diffusion region, causing deterioration of emission efficiency. Thus, the laser device is more likely to incur deteriorations of reliability.

### SUMMARY OF THE INVENTION

Accordingly, an object of the present invention is to provide a semiconductor laser device which has a reduced electrical resistance and is prevented from deteriorations of laser device characteristics, as well as providing a manufacturing method therefor.

In order to accomplish the above object, a semiconductor laser device according to the present invention has compound semiconductor layers formed on a substrate; a striped ridge portion which is formed on the compound semiconductor layer and which includes a plurality of layers, a topmost layer thereof being a contact layer; a dielectric film formed on both sides of the ridge portion; and an on-ridge electrode which is in contact with a top face and side faces of the contact layer. And, side faces of the ridge portion except the contact layer which is in contact with the on-ridge electrode are covered with the dielectric film, and the contact layer has a layer thickness larger than a film thickness of a portion of the dielectric film that is roughly parallel to the substrate.

In the semiconductor laser device with the above structure, by the on-ridge electrode being in contact with the top face and side faces of the contact layer, the area of contact between the on-ridge electrode and the contact layer is increased, so that the electrical resistance can be lowered.

Also, since the side faces of the ridge portion except the contact layer are covered with the dielectric film, although the on-ridge electrode is formed on the top face and side faces of the contact layer, constituent elements of the on-ridge electrode can be inhibited from being diffused into the ridge portion except the contact layer. Therefore, the semiconductor laser device is prevented from deteriorations of its device characteristics. For instance, the semiconductor laser device is prevented from deterioration of its service life characteristic.

Also, the contact layer having a layer thickness larger than a film thickness of the portion of the dielectric film roughly parallel to the substrate ensures that the side faces of the ridge portion except the contact layer are covered with the dielectric film.

In one embodiment, the semiconductor laser device further has terrace portions formed on both sides of the ridge portion, with a recess portion sandwiched between the ridge portion and each terrace portion, and the recess portions and the terrace portions are buried in the dielectric film.

In this embodiment, since the terrace portions are formed on both sides of the ridge portion with the respective recess portions sandwiched therebetween, the ridge portion is prevented from being damaged during the manufacturing process.

Furthermore, even in the case where junction down mounting is executed for improvement of heat dissipation of the semiconductor laser device, concentration of loads to the ridge portion during the mounting operation can be avoided. Moreover, due to the provision of the terrace portions on both sides of the ridge portion with the recess portions sandwiched therebetween, the chip, or the laser device, is prevented from tilting during the mounting process.

In one embodiment, the semiconductor laser device further has an Au plating film which is formed over the ridge portion and which contains Au.

In this embodiment, the Au plating film on the ridge portion allows efficient discharge of heat from the ridge portion. Thus, heat dissipation can be improved.

Also, putting the plating film in contact with part of the side faces of the contact layer would further improve heat dissipation.

In one embodiment, the on-ridge electrode includes a metal film which is formed between the Au plating film and the ridge portion and which includes a barrier metal that prevents diffusion of Au.

In this embodiment, the metal film between the Au plating film and the ridge portion ensures prevention of Au of the Au plating film from being diffused into the ridge portion except the contact layer.

On the other hand, a method for manufacturing a semiconductor laser device according to the preset invention includes a first step of forming compound semiconductor layers on a substrate; a second step of forming on the compound semiconductor layers a striped ridge portion which includes a plurality of layers, a topmost layer thereof being a contact layer; a third step of forming a dielectric film on the compound semiconductor layers and the ridge portion; a fourth step of forming a resist pattern on the dielectric film such that portions of the dielectric film present on a top face and side faces of the contact layer are exposed; a fifth step of removing the dielectric film exposed from the resist pattern by etching such that the top face and side faces of the contact layer are exposed; and a sixth step of forming an on-ridge electrode which is in contact with the top face and side faces of the contact layer, wherein in the third step, the dielectric film is formed such that a layer thickness of the contact layer is larger than a film thickness of the dielectric film present on the contact layer.

In this method, after forming compound semiconductor layers on a substrate, a striped ridge portion including a plurality of layers, of which the topmost layer is a contact layer, is formed on the compound semiconductor layers. Then a dielectric film is formed on the compound semiconductor layers and the ridge portion. At this time, the dielectric film is formed such that the layer thickness of the contact layer is larger than the film thickness of the dielectric film present on the contact layer. Subsequently, a resist pattern is formed on the dielectric film in such a manner that portions of the dielectric film present on a top face and side faces of the contact layer are exposed. Then, the dielectric film is partially removed by etching using the resist pattern, so that the top face and side faces of the contact layer are exposed. Thereafter, an on-ridge electrode is formed, which is in contact with the top face and side faces of the contact layer.

As shown above, by the formation of the on-ridge electrode that is in contact with the top face and side faces of the contact layer, the contact area between the on-ridge electrode and the contact layer is increased, so that the electrical resistance can be lowered.

Also, by setting the layer thickness of the contact layer larger than the film thickness of the dielectric film present on the contact layer, the side faces of the ridge portion except those of the contact layer are prevented from being exposed when the dielectric film is partially etched by using the resist pattern. That is, the side faces of the ridge portion except the contact layer are allowed to remain covered with the dielectric film. Therefore, constituent elements of the on-ridge electrode are inhibited from being diffused into the ridge portion except the contact layer in spite that the on-ridge electrode is formed on the top face and side faces of the contact layer. As a result, the semiconductor laser device is prevented from deteriorations of its laser device characteristics. For instance, the semiconductor laser device is prevented from deterioration of its service life characteristic.

Further, even with variations of the layer thickness of a resist layer to be formed into the resist pattern or variations of exposure conditions for the formation of the resist pattern, the side faces of the ridge portion except the contact layer is prevented from being exposed by setting the layer thickness of the contact layer larger than the film thickness of the dielectric film present on the contact layer.

In one embodiment, the etching is wet etching.

If the etching of the dielectric film is implemented by dry etching, the etching of the dielectric film may cause the resist pattern to be transformed, or altered in properties. Then, it is difficult to remove the resist pattern after the etching of the dielectric film.

In contrast to this, when the etching of the dielectric film is implemented by wet etching, alteration of the resist pattern due to the etching of the dielectric film is avoided. Therefore, the resist pattern can easily be removed after the etching of the dielectric film. Thus, the on-ridge electrode can be formed easily by a liftoff process with the use of the resist pattern.

In one embodiment, the on-ridge electrode is formed by liftoff process using the resist pattern.

In this embodiment, the manufacture of the semiconductor laser device can be simplified with the number of manufacturing steps cut down.

In one embodiment, in the third step, the dielectric film is formed such that the layer thickness of the contact layer becomes larger than a thickness resulting from adding 0.2 μm to the film thickness of the dielectric film present on the contact layer.

The layer thickness of the resist layer to be formed into the resist pattern will vary to a large extent especially when terrace portions are formed on both sides of the ridge portion with respective recess portions disposed therebetween. In the embodiment, however, even in that case, the side faces of the ridge portion except the contact layer is prevented from being exposed because of the layer thickness of the contact layer-being larger than the sum 0.2 μm plus the film thickness of the dielectric film present on the contact layer.

In one embodiment, the sixth step includes a seventh step of forming, over the ridge portion, a metal film containing a barrier metal for prevention of Au diffusion, and the method further includes an eighth step of forming over the metal film an Au plating film containing Au.

In this embodiment, after a metal film including a barrier metal for prevention of Au diffusion is formed on the ridge portion, an Au plating film containing Au is formed on the metal film. Thus, Au atoms in the Au plating film are prevented from being diffused into the ridge portion except the contact layer.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a schematic sectional view of a semiconductor laser device according to a first embodiment of the present invention;

FIGS. 2A-2H are manufacturing process diagrams of the first embodiment;

FIG. 3 is a schematic sectional view of a semiconductor laser device according to a second embodiment of the present invention;

FIGS. 4A-4K are manufacturing process diagrams of the second embodiment;

FIG. 5 is a schematic sectional view of a semiconductor laser device according to a third embodiment of the present invention;

FIG. 6 is a schematic sectional view of a semiconductor laser device according to a fourth embodiment of the present invention;

FIGS. 7A-7F are manufacturing process diagrams of the fourth embodiment;

FIG. 8 is a schematic sectional view of a prior art semiconductor laser device;

FIGS. 9A-9E are manufacturing process diagrams of another prior art semiconductor laser device; and

FIGS. 10A-10D are enlarged sectional views of a region of maximum resist layer thickness and a region of minimum resist layer thickness in the steps shown in FIGS. 9B-9D.

### DETAILED DESCRIPTION OF THE INVENTION

In the following embodiments, AlGaInP red semiconductor laser devices will be described. The present invention is, however, not limited to red semiconductor laser devices and manufacturing methods therefor.

Also, in the following embodiments, a ridge portion is buried in a dielectric film to implement current constriction and light confinement at the ridge portion. However, a film similar in function to a dielectric film, if any, may be used to bury the ridge portion. For instance, an insulating film may be used instead of a dielectric film.

Hereinbelow, the present invention will be described in detail by embodiments thereof illustrated in the accompanying drawings. It should be noted that the present invention is not limited to the following embodiments.

### FIRST EMBODIMENT

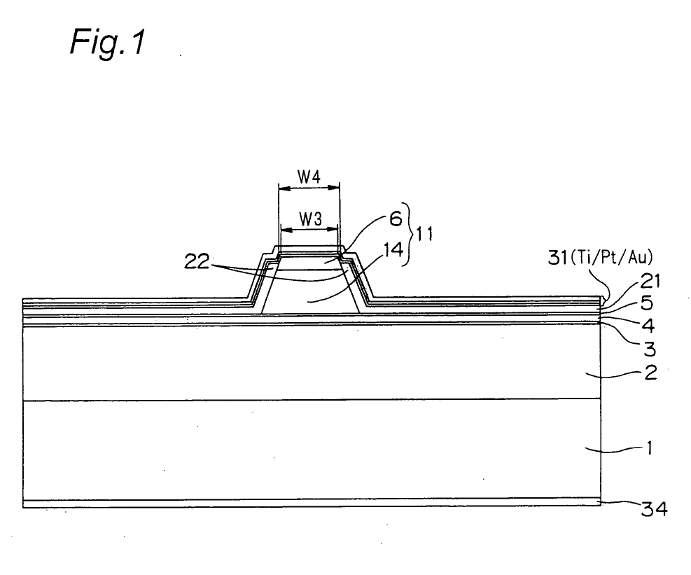

FIG. 1 shows a schematic sectional view of a semiconductor laser device according to a first embodiment of the present invention.

The semiconductor laser device has an n-(Al_{0.7}Ga_{0.3})_{0.5}In_{0.5}P first cladding layer 2, a quantum well active layer 3, a p-(Al_{0.7}Ga_{0.3})_{0.5}In_{0.5} P second cladding layer 4, and a p-In_{0.5}Ga_{0.5}P etching stopper layer 5, and these layers are sequentially stacked in this order on an n-GaAs substrate 1 as an example of the substrate. The n-(Al_{0.7}Ga_{0.3})_{0.5}In_{0.5}P first cladding layer 2, the quantum well active layer 3, the p-(Al_{0.7}Ga_{0.3})_{0.5}In_{0.5}P second cladding layer 4 and the p-In_{0.5}Ga_{0.5}P etching stopper layer 5 form an example of the compound semiconductor layers.

The quantum well active layer 3 is composed of two In_{0.5}Ga_{0.5}P well layers, a single (Al_{0.7}Ga_{0.3})_{0.5}In_{0.5}P barrier layer placed between the two well layers, and two (Al_{0.7}Ga_{0.3})_{0.5}In_{0.5}P guide layers that sandwich the well layers and the barrier layer therebetween.

On the etching stopper layer 5 is disposed a striped ridge portion 11 that is composed of a p-(Al_{0.7}Ga_{0.3})_{0.5}In_{0.5}P third cladding layer 14 and a p-GaAs contact layer 6. The ridge portion 11 is extending in a direction perpendicular to the plane of the drawing sheet of FIG. 1.

The side faces of the ridge portion 11, the top face of the p-In_{0.5}Ga_{0.5}P etching stopper layer 5 and the top faces and side faces of the terrace portions 12 are covered with a dielectric film 21, and a p-side electrode 31 as an example of the on-ridge electrode is provided on the dielectric film 21 and the ridge portion 11. The p-side electrode 31 is composed of a Ti film having high adhesion to the dielectric film 21, a Pt film formed on the Ti film, and an Au film formed on the Pt film. The p-side electrode 31 covers even the top faces and side faces of the terrace portions 12.

Boundaries between edge portions 22 of the dielectric film 21 and the p-side electrode 31 fall halfway on the side faces of the p-GaAs contact layer 6. That is, the dielectric film 21 covers the whole side faces of the p-(Al_{0.7}Ga_{0.3})_{0.5}In_{0.5}P third cladding layer 14 and lower portions (portions on the n-GaAs substrate 1 side) of the side faces of the p-GaAs contact layer 6. Upper portions (portions on the side farther from the n-GaAs substrate 1) of the side faces of the p-GaAs contact layer 6 are not covered with the dielectric film 21. Also, the p-side electrode 31 is in contact with the whole generally flat top face of the p-GaAs contact layer 6, and also with part of each side face of the p-GaAs contact layer 6. That is, the p-side electrode 31 is disposed such that an electric current caused by the p-side electrode 31 is passed through the whole top face of the p-GaAs contact layer 6 and part of the side faces of the p-GaAs contact layer 6 so as to be injected into the ridge portion 11.

The layer thickness of the p-GaAs contact layer 6 is larger than the film thickness of parts of the dielectric film 21 that are generally parallel to the n-GaAs substrate 1. That is, the parts of the dielectric film 21 that are in contact with the p-In_{0.5}Ga_{0.5}P etching stopper layer 5 have a film thickness smaller than the layer thickness of the p-GaAs contact layer 6.

Reference numeral 34 in FIG. 1 denotes an n-side electrode.

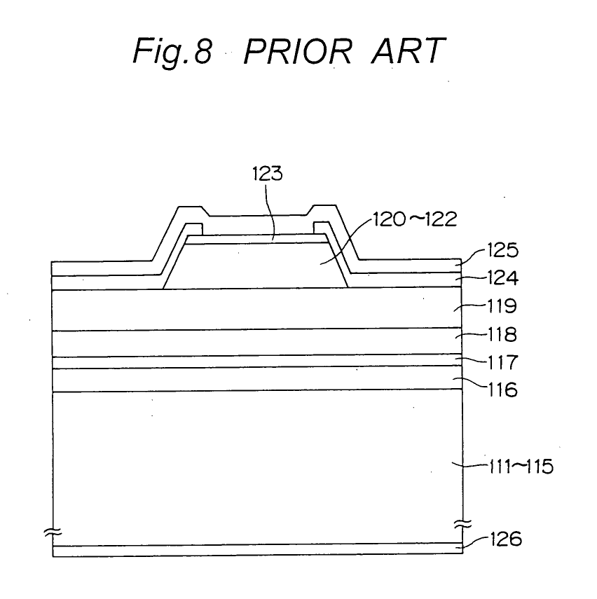

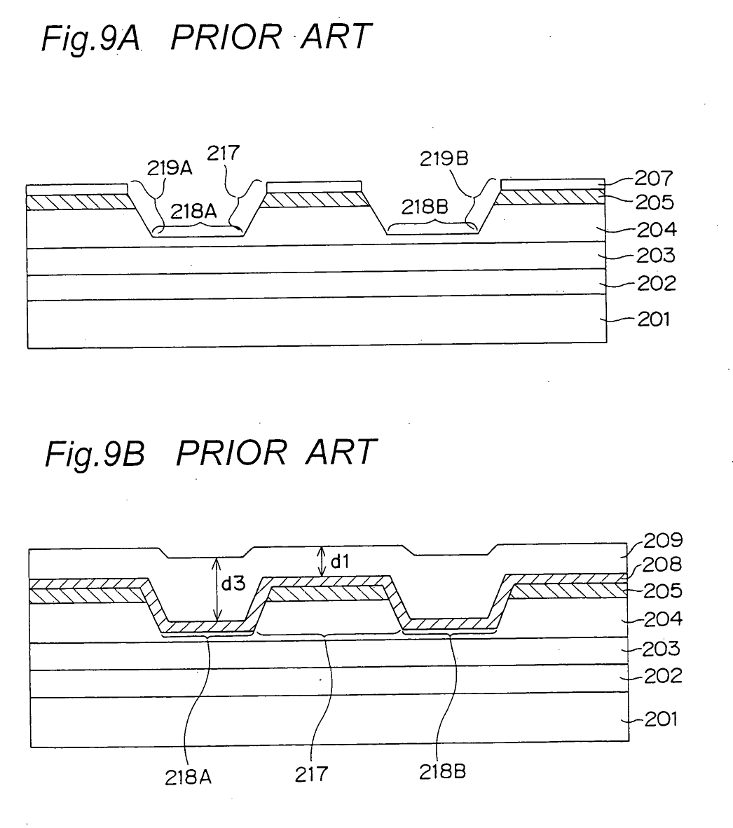

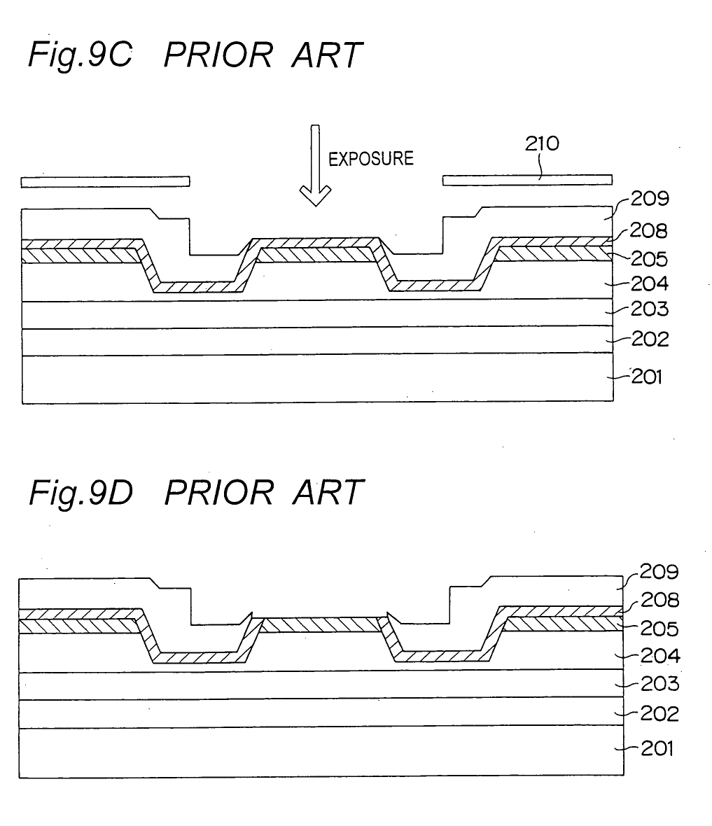

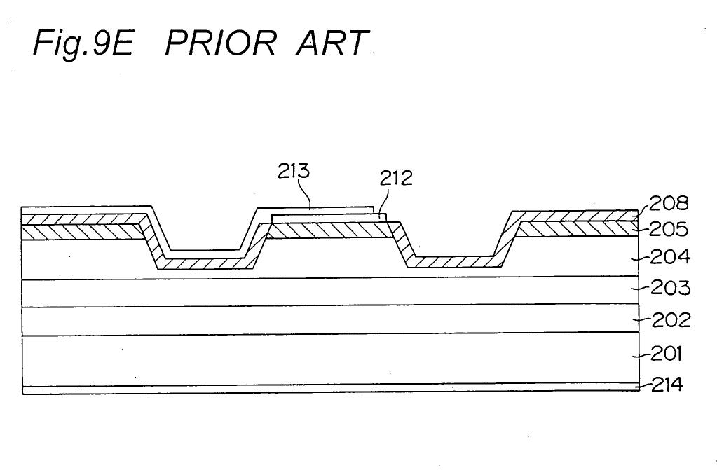

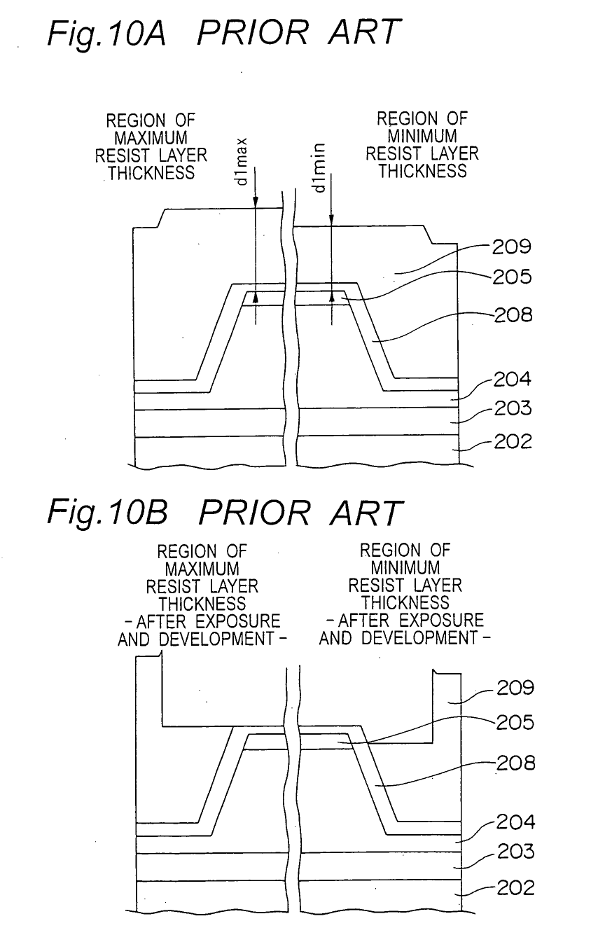

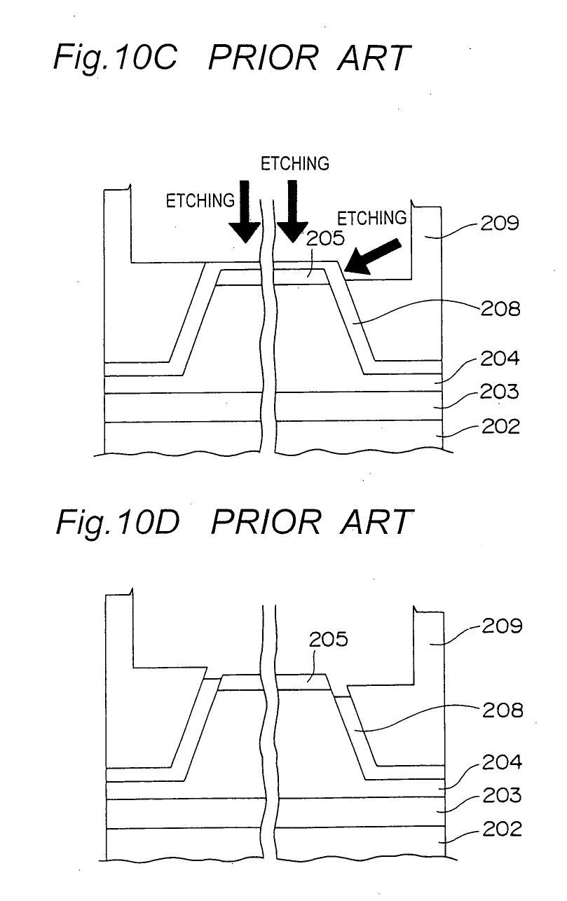

With the semiconductor laser device of this constitution, since the p-side electrode 31 is in contact with the overall top face of the p-GaAs contact layer 6 and part of the side faces of the p-GaAs contact layer 6, the contact area between the p-side electrode 31 and the ridge portion 11 becomes larger than in the conventional semiconductor laser devices of FIGS. 8 and 9. Accordingly, the semiconductor laser device of this embodiment has become capable of lowering the electrical resistance than in the conventional semiconductor laser device of FIGS. 8 and 9.

Particularly when the inclination angle of the side faces of the p-GaAs contact layer 6 with respect to the p-In_{0.5}Ga_{0.5}P etching stopper layer 5 is less than 90°, i.e., when a width W3 of the top face of the p-GaAs contact layer 6 is smaller than an inner-edge width W4 between the edges 22 of the dielectric film, the contact of the p-side electrode 31 with the top face and side faces of the p-GaAs contact layer 6 is effective for reduction in electrical resistance.

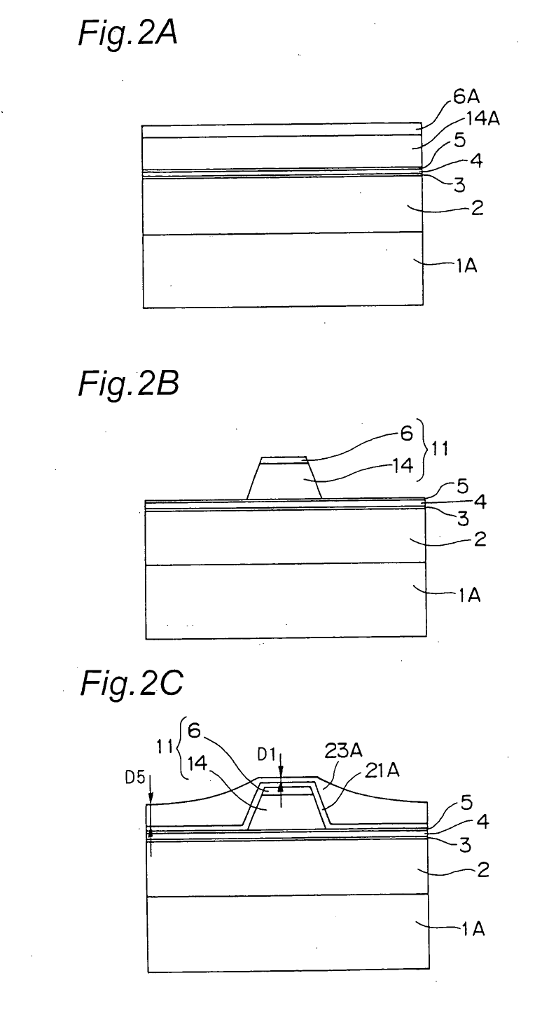

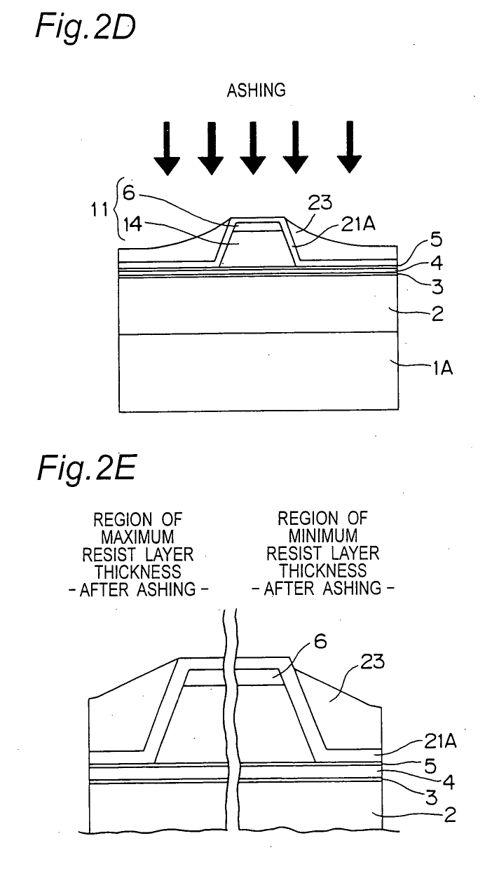

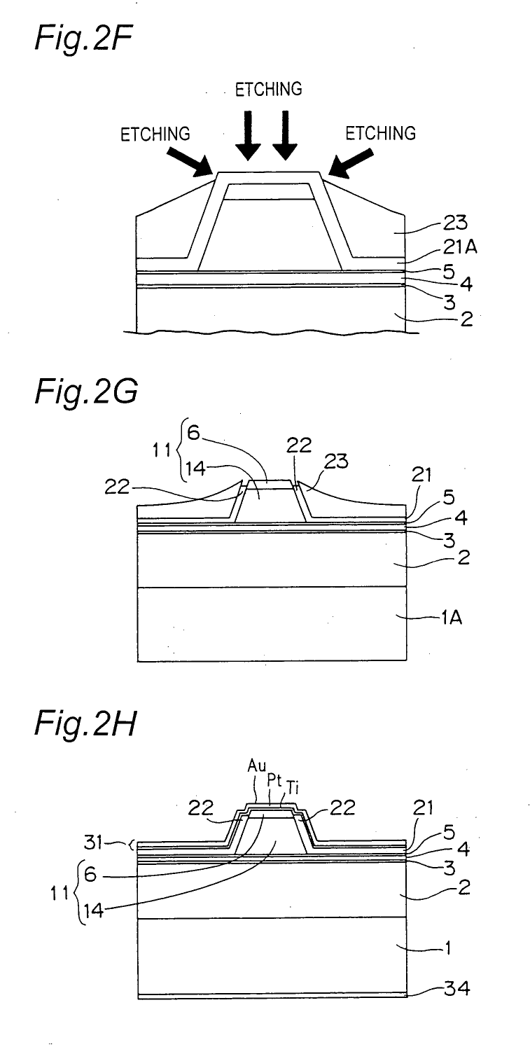

FIGS. 2A to 2H show manufacturing process diagrams of the semiconductor laser device.

First, as shown in FIG. 2A, a 2.0 μm thick n-(Al_{0.7}Ga_{0.3})_{0.5}In_{0.5}P first cladding layer 2, a quantum well active layer 3, a 0.2 to 0.3 μm thick p-(Al_{0.7}Ga_{0.3})_{0.5}In_{0.5}P second cladding layer 4, a 50 Å thick p-In_{0.5}Ga_{0.5}P etching stopper layer 5, a p-(Al_{0.7}Ga_{0.3})_{0.5}In_{0.5}P third cladding layer 14A, and a 0.3 μm thick p-GaAs contact layer 6A are formed in this order on a 300 to 350 μm thick n-GaAs substrate 1A.

In forming the quantum well active layer 3, each In_{0.5}Ga_{0.5}P well layer is set to a thickness of 80 Å, and the (Al_{0.7}Ga_{0.3})_{0.5}In_{0.5}P barrier layer is set to a thickness of 50 Å, and each (Al_{0.7}Ga_{0.3})_{0.5}In_{0.5}P guide layer is set to a thickness of 300 Å.

Next, the p-(Al_{0.7}Ga_{0.3})_{0.5}In_{0.5}P third cladding layer 14A and the p-GaAs contact layer 6A is partially removed to form a 1.5 to 3 μm wide striped ridge portion 11 composed of a p-(Al_{0.7}Ga_{0.3})_{0.5}In_{0.5}P third cladding layer 14 and a p-GaAs contact layer 6, as shown in FIG. 2B.

Next, as shown in FIG. 2C, a dielectric film 21A is deposited all over the wafer that contains the n-GaAs substrate 1A, the n-(Al_{0.7}Ga_{0.3})_{0.5}In_{0.5}P first cladding layer 2, the quantum well active layer 3, the p-(Al_{0.7}Ga_{0.3})_{0.5}In_{0.5}P second cladding layer 4, the p-In_{0.5}Ga_{0.5}P etching stopper layer 5, and the ridge portion 11. The dielectric film 21A is deposited such that its film thickness on the p-GaAs contact layer 6 is 0.2 μm.

Next, a positive-type resist layer 23A is formed on the dielectric film 21A. At this time, spin coating conditions including the viscosity of the resist material are adjusted so that the resist layer thickness D1 on the top face of the ridge portion 11 becomes smaller than a resist layer thickness D5 of both sides of the ridge portion 11.

Next, ashing is performed all over the wafer, by which the resist layer 23A present on top of the p-GaAs contact layer 6 is removed. As a result of this, a resist layer 23 as an example of the resist pattern is formed on the dielectric film 21A as shown in FIG. 2D.

The ashing amount in the above ashing process is controlled by controlling the ashing power and time such that just the entire resist layer 23A, and neither more nor less, present on top of the p-GaAs contact layer 6 is removed. In more detail, since the resist layer thickness D1 on the top face of the p-GaAs contact layer 6 varies within the wafer, the ashing process is carried out setting an ashing amount corresponding to a maximum value of the resist layer thickness D1 in its distribution within the wafer.

In the case where such an ashing is performed, since the resist layer thickness D5 at a side of the ridge portion 11 is larger than the resist layer thickness D1 on top of the ridge portion 11, the resist layer 23 remains at the sides of the ridge portion 11.

The ashing conditions are set in accordance with a region where the resist layer thickness D1 on the top face of the p-GaAs contact layer 6 is at the maximum. Therefore, after the ashing has been performed, only the top face of the dielectric film 21 is exposed in the region where the resist layer thickness on the p-GaAs contact layer 6 is at the maximum, as shown in the left hand of FIG. 2E. However, as a whole, the ashing is carried out on the wafer with an ashing amount larger than an ashing amount with which only the resist layer 23A present on the top face of the p-GaAs contact layer 6 is just removed. As a result of this, for example in a region where the resist layer thickness on the p-GaAs contact layer 6 is at the minimum, not only the top face of the dielectric film 21 but also an upper portion of the side face of the dielectric film 21A is exposed, as shown in the right hand of FIG. 2E.

Next, as shown in FIG. 2F, using the resist layer 23 as an example of the resist pattern as an etching mask, the dielectric film 21A exposed from the resist layer 23 is removed by etching with buffered hydrofluoric acid. In this process, in the region having the minimum resist layer thickness on the p-GaAs contact layer 6, the etching of the dielectric film 21A progresses not only from above but also from sideways. More specifically, in etching removal of the 0.2 μm dielectric film 21A on the p-GaAs contact layer 6, the dielectric film 21A present in side portions of the p-GaAs contact layer 6 is also subjected to the 0.2 μm etching. In this case, since the layer thickness of the p-GaAs contact layer 6 is as thick as 0.3 μm, the etching of the dielectric film placed in side portions of the p-GaAs contact layer 6 is stopped within the side faces of the p-GaAs contact layer 6, as shown in FIG. 2G. That is, the side faces of the p-(Al_{0.7}Ga_{0.3})_{0.5}In_{0.5}P third cladding layer 14 are easily prevented from being exposed. Accordingly, the upper-side (the side farther from the n-GaAs substrate 1A) inner edges of the edge portions 22 of the dielectric film 21 are prevented from being located on the p-(Al_{0.7}Ga_{0.3})_{0.5}In_{0.5}P third cladding layer 14. As a result, the top face of the p-GaAs contact layer 6 and upper portions of the side faces of the p-GaAs contact layer 6 only are exposed from the resist layer 23.

Next, after the removal of the resist layer 23, a p-side electrode 31 composed of a Ti film, a Pt film and an Au film is formed on the p-GaAs contact layer 6 and the dielectric film 21, as shown in FIG. 2H. The p-side electrode 31 is in contact with the entirety of the top face of the p-GaAs contact layer 6 and only upper portions of the side faces of the p-GaAs contact layer 6 with respect to the ridge portion 11. Accordingly, the electric current from the p-side electrode 31 is injected into the ridge portion 11 through the top face and side faces of the p-GaAs contact layer 6.

Next, the bottom face of the n-GaAs substrate 1A is polished, whereby an n-GaAs substrate 1 having a wafer thickness (50 to 130 μm thick) is obtained, which thickness is suitable for dividing the wafer into semiconductor lasers.

Finally, an n-side electrode 34 is formed on the bottom face of the n-GaAs substrate 1, followed by alloying of the p-side electrode 31 and the n-side electrode 34. As a result, a multilayered structure of a ridge waveguide type semiconductor laser wafer is completed.

In the manufacture of the semiconductor laser device, regions where the side faces of the dielectric film 21A are exposed would take place due to variations of the resist layer thickness and/or the ashing amount in the photolithography process for the removal of the dielectric film. However, since the layer thickness of the p-GaAs contact layer 6 is set larger than the thickness of the dielectric film 21A deposited on the p-GaAs contact layer 6, it is possible, even with the etching of the dielectric film 21A in the above-described regions, to prevent the side faces of the p-(Al_{0.7}Ga_{0.3})_{0.5}In_{0.5}P third cladding layer 14 from being exposed while fully removing the dielectric film 21A on top of the p-GaAs contact layer 6. It follows that the boundaries between the edge portions 22 of the dielectric film 21 and the p-side electrode 31 are formed on the side faces of the p-GaAs contact layer 6 with high controllability.

Also, since the side faces of the p-(Al_{0.7}Ga_{0.3})_{0.5}In_{0.5}P third cladding layer 14 do not fail to be covered with the dielectric film 21, the transverse mode controllability is improved and moreover Au diffusion into the p-(Al_{0.7}Ga_{0.3})_{0.5}In_{0.5}P third cladding layer 14 is prevented by the dielectric film 21 so that the reliability is improved.

In the structure of FIG. 1, the boundaries between the edge portions 22 of the dielectric film 21 and the p-side electrode 31 are located so as to be in contact with central portions of the side faces of the p-GaAs contact layer 6. However, the boundaries may be in contact with, for example, upper ends of the side faces of the p-GaAs contact layer 6, or with lower ends of the side faces of the p-GaAs contact layer 6. That is, the p-GaAs contact layer 6-side edges of the boundaries have only to be placed between a plane containing the top face of the p-GaAs contact layer 6 and a plane containing the bottom face of the p-GaAs contact layer 6.

### SECOND EMBODIMENT

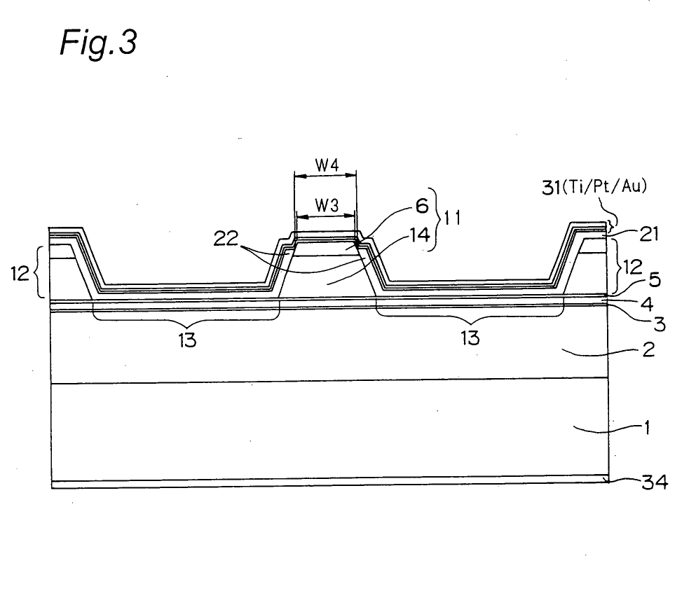

FIG. 3 shows a schematic sectional view of a semiconductor laser device according to a second embodiment of the present invention.

The semiconductor laser device has an n-(Al_{0.7}Ga_{0.3})_{0.5}In_{0.5}P first cladding layer 2, a quantum well active layer 3, a p-(Al_{0.7}Ga_{0.3})_{0.5}In_{0.5}P second cladding layer 4, and a p-In_{0.5}Ga_{0.5}P etching stopper layer 5, and these layers are sequentially stacked in this order on an n-GaAs substrate 1 as an example of the substrate. The n-(Al_{0.7}Ga_{0.3})_{0.5}In_{0.5}P first cladding layer 2, the quantum well active layer 3, the p-(Al_{0.7}Ga_{0.3})_{0.5}In_{0.5}P second cladding layer 4 and the p-In_{0.5}Ga_{0.5}P etching stopper layer 5 form an example of the compound semiconductor layers.

The quantum well active layer 3 is composed of two In_{0.5}Ga_{0.5}P well layers, a single (Al_{0.7}Ga_{0.3})_{0.5}In_{0.5}P barrier layer placed between the two well layers, and two (Al_{0.7}Ga_{0.3})_{0.5}In_{0.5}P guide layers that sandwich the well layers and the barrier layer therebetween.

On the etching stopper layer 5 is disposed a striped ridge portion 11 that is composed of a p-(Al_{0.7}Ga_{0.3})_{0.5}In_{0.5}P third cladding layer 14 and a p-GaAs contact layer 6. Then, on both sides of the ridge portion 11 are provided striped terrace portions 12 for reducing mechanical damages that the ridge portion 11 may incur during the handling of the semiconductor layer wafer or the mounting of the laser chip. The terrace portions 12 are formed of a p-(Al_{0.7}Ga_{0.3})_{0.5}In_{0.5}P layer and a p-GaAs layer, like the ridge portion 11. Further, there are striped recess portions 13 between the ridge portion 11 and each of the terrace portions 12, respectively. The ridge portion 11, the terrace portions 12, and the recess portions 13 formed in this way are extending in a direction perpendicular to the plane of the drawing sheet of FIG. 3.

The side faces of the ridge portion 11, the top face of the p-In_{0.5}Ga_{0.5}P etching stopper layer 5 and the top faces and side faces of the terrace portions 12 are covered with a dielectric film 21, and a p-side electrode 31 as an example of the on-ridge electrode is provided on the dielectric film 21 and the ridge portion 11. The p-side electrode 31 is composed of a Ti film having high adhesion to the dielectric film 21, a Pt film formed on the Ti film, and an Au film formed on the Pt film. The p-side electrode 31 covers even the top faces and side faces of the terrace portions 12.

Boundaries between edge portions 22 of the dielectric film 21 and the p-side electrode 31 fall halfway on the side faces of the p-GaAs contact layer 6. That is, the dielectric film 21 covers the whole side faces of the p-(Al_{0.7}Ga_{0.3})_{0.5}In_{0.5}P third cladding layer 14 and lower portions (portions on the n-GaAs substrate 1 side) of the side faces of the p-GaAs contact layer 6. Upper portions (portions on the side farther from the n-GaAs substrate 1) of the side faces of the p-GaAs contact layer 6 are not covered with the dielectric film 21. Also, the p-side electrode 31 is in contact with the whole generally flat top face of the p-GaAs contact layer 6, and also with part of each side face of the p-GaAs contact layer 6. That is, the p-side electrode 31 is disposed such that an electric current caused by the p-side electrode 31 is passed through the whole top face of the p-GaAs contact layer 6 and part of the side faces of the p-GaAs contact layer 6 so as to be injected into the ridge portion 11.

The layer thickness of the p-GaAs contact layer 6 is larger than the film thickness of parts of the dielectric film 21 that are generally parallel to the n-GaAs substrate 1. That is, the parts of the dielectric film 21 that are in contact with the p-In_{0.5}Ga_{0.5}P etching stopper layer 5 have a film thickness smaller than the layer thickness of the p-GaAs contact layer 6.

Reference numeral 34 in FIG. 3 denotes an n-side electrode.

With the semiconductor laser device of this constitution, since the p-side electrode 31 is in contact with the overall top face of the p-GaAs contact layer 6 and part of the side faces of the p-GaAs contact layer 6, the contact area between the p-side electrode 31 and the ridge portion 11 becomes larger than in the conventional semiconductor laser devices of FIGS. 8 and 9. Accordingly, the semiconductor laser device of this embodiment has become capable of lowering the electrical resistance than in the conventional semiconductor laser device of FIGS. 8 and 9.

Particularly when the inclination angle of the side faces of the p-GaAs contact layer 6 with respect to the p-In_{0.5}Ga_{0.5}P etching stopper layer 5 is less than 90°, i.e., when a width W3 of the top face of the p-GaAs contact layer 6 is smaller than an inner-edge width W4 between the edges 22 of the dielectric film, the contact of the p-side electrode 31 with the top face and side faces of the p-GaAs contact layer 6 is effective for reduction in electrical resistance.

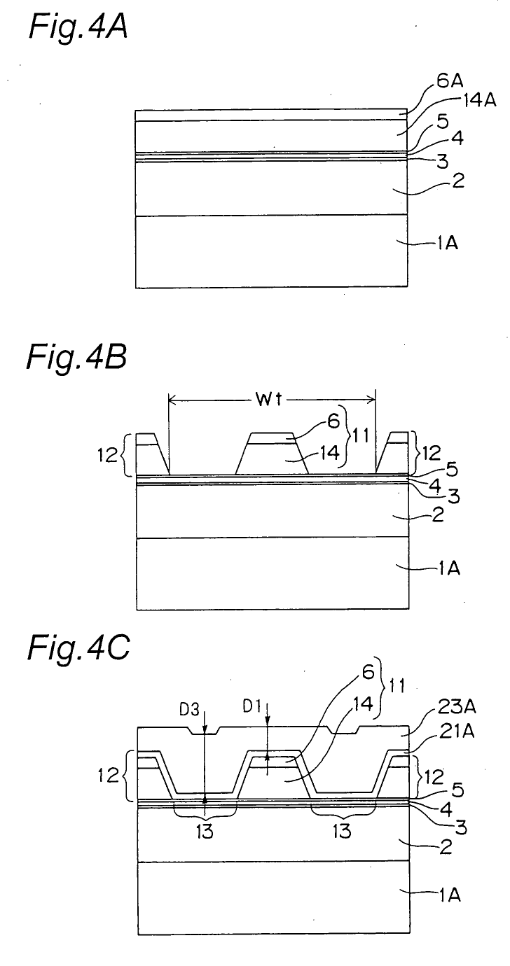

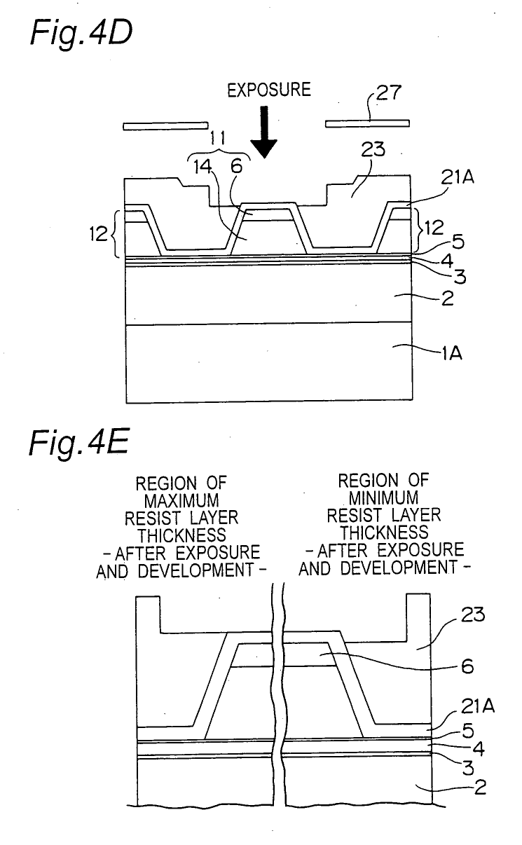

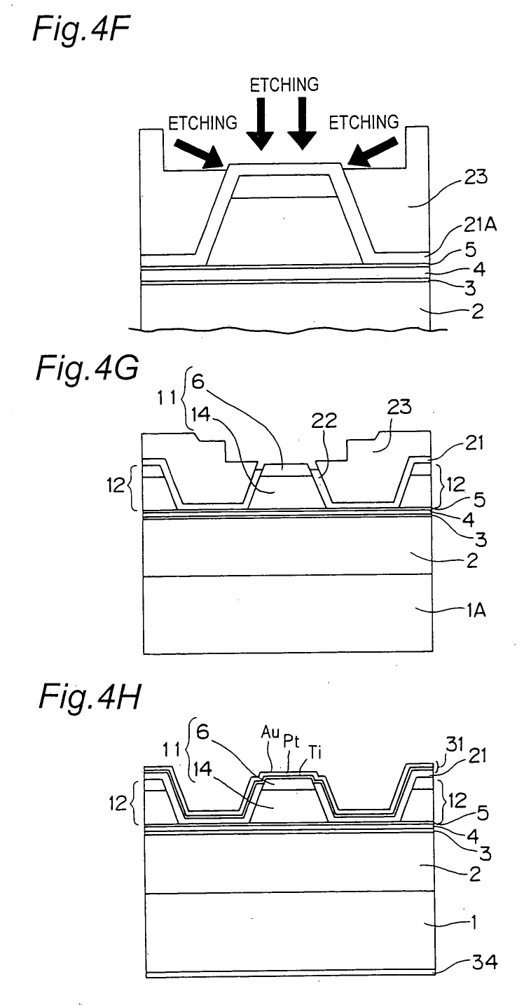

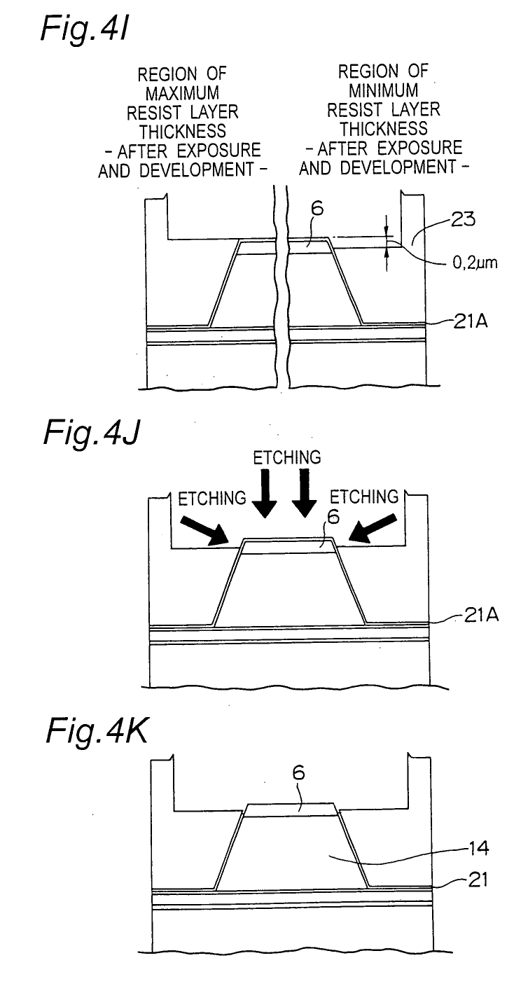

FIGS. 4A to 4H show manufacturing process diagrams of the semiconductor laser device.

In the manufacturing method of the semiconductor laser device, first, as shown in FIG. 4A, a 2.0 μm thick n-(Al_{0.7}Ga_{0.3})_{0.5}In_{0.5}P first cladding layer 2, a quantum well active layer 3, a 0.2 to 0.3 μm thick p-(Al_{0.7}Ga_{0.3})_{0.5}In_{0.5}P second cladding layer 4, a 50 Å thick p-In_{0.5}Ga_{0.5}P etching stopper layer 5, a p-(Al_{0.7}Ga_{0.3})_{0.5}In_{0.5}P third cladding layer 14A, and a 0.4 μm thick p-GaAs contact layer 6A are formed in this order on a 300 to 350 μm thick n-GaAs substrate 1A.

In forming the quantum well active layer 3, each In_{0.5}Ga_{0.5}P well layer is set to a thickness of 80 Å, and the (Al_{0.7}Ga_{0.3})_{0.5}In_{0.5}P barrier layer is set to a thickness of 50 Å, and each (Al_{0.7}Ga_{0.3})_{0.5}In_{0.5}P guide layer is set to a thickness of 300 Å.

Next, the p-(Al_{0.7}Ga_{0.3})_{0.5}In_{0.5}P third cladding layer 14A and the p-GaAs contact layer 6A is partially removed to form a 1.5 to 3 μm wide striped ridge portion 11 composed of a p-(Al_{0.7}Ga_{0.3})_{0.5}In_{0.5}P third cladding layer 14 and a p-GaAs contact layer 6, as shown in FIG. 4B. Further, simultaneously with the formation of the ridge portion 11, striped terrace portions are formed on both sides of the ridge portion 11 and recess portions 13 are formed between the ridge portion 11 and the terrace portions 12. A distance Wt between the terrace portions 12 is set to 40 μm.

Next, as shown in FIG. 4C, a dielectric film 21A is deposited all over the wafer that contains the n-GaAs substrate 1A, the n-(Al_{0.7}Ga_{0.3})_{0.5}In_{0.5}P first cladding layer 2, the quantum well active layer 3, the p-(Al_{0.7}Ga_{0.3})_{0.5}In_{0.5}P second cladding layer 4, the p-In_{0.5}Ga_{0.5}P etching stopper layer 5, the ridge portion 11 and the terrace portions 12. The dielectric film 21A is deposited such that its film thickness on the p-GaAs contact layer 6 is 0.2 μm.

Next, a positive-type resist layer 23A is formed on the dielectric film 21A. The formation of this resist layer 23A is done in such a way that the recess portions 13 are filled with the resist layer 23A, so that the top face of the resist layer 23A is smoothed. Also, for the formation of the resist layer 23A, spin coating conditions including the viscosity of the resist material are adjusted so that the resist layer thickness D1 on the top face of the ridge portion 11 (top face of the p-GaAs contact layer 6) becomes smaller than a resist layer thickness D3 of both sides of the ridge portion 11. For instance, the resist layer thickness D3 is set to about 2.0 μm and the resist layer thickness D1 is set to about 0.7 μm.

Also, in the formation of the resist layer 23A, since the terrace portions 12 are present on both sides of the ridge portion 11 with the recess portions 13 sandwiched therebetween, the recess portions 13, which form depressions, can be easily filled up with the resist layer 23A.

Next, as shown in FIG. 4D, an exposure mask 27 is aligned such that the transmission region of the exposure mask 27 falls on the entirety of the ridge portion 11 and part of the recess portions 13, and thereafter exposure to light is performed. In this process, the width of the transmission region of the exposure mask 27 is one half of the distance Wt between the terrace portions 12. That is, the width of the transmission region of the exposure mask 27 is 20 μm.

The exposure alignment can easily be achieved only by placing the transmission region of the exposure mask 27 over the top face and side faces of the ridge portion 11 and by making the transmission region of the exposure mask 27 not overlapped with the terrace portions 12.

The exposure is carried out in such a fashion that the resist layer 23A on the top face of the p-GaAs contact layer 6 can be fully removed by development. This is implemented by controlling the exposure time so as to adjust the light exposure of the resist layer 23A. That is, the exposure process is implemented as the so-called “just exposure”. More specifically, since the resist layer thickness D1 on the top face of the p-GaAs contact layer 6 has variations within the wafer, the exposure process is carried out with an exposure amount or energy corresponding to a maximum value of the resist layer thickness D1 in its distribution within the wafer.

In the case where such exposure is carried out, the resist layer 23A that is not located on top of the ridge portion 11 but overlapping with the transmission region of the exposure mask 27 results in a half exposed state. Therefore, even if the resist layer 23A on the top face of the p-GaAs contact layer 6 is fully removed by development, the resist layer 23A that is not located on top of the ridge portion 11 but overlapping with the transmission region of the exposure mask 27 partly remains left.

Also, the exposure condition is set in correspondence to the region where the resist layer thickness D1 on the top face of the p-GaAs contact layer 6 is at the maximum. Therefore, performing the development process after the exposure process causes only the top face of the dielectric film 21A to be exposed in the region where the resist layer thickness D1 on the top face of the p-GaAs contact layer 6 is at the maximum, as shown in the left hand side of FIG. 4E. However, as a whole, the exposure process is carried out on the wafer with an exposure amount larger than an exposure amount with which only the resist layer 23A present on the top face of the p-GaAs contact layer 6 is just removed. As a result of this, for example in a region where the resist layer thickness D1 on the top face of the p-GaAs contact layer 6 is at the minimum, not only the top face of the dielectric film 21 but also an upper portion of the side face of the dielectric film 21A is exposed as shown in the right hand of FIG. 4E.

The reason why the transmission region of the exposure mask 27 is not placed over the terrace portions 12 is to prevent the resist layer 23A on the terrace portions 12 from being removed by the after-exposure development.

In the case of a ridge portion provided with terrace portions, the resist coating thickness for removal of the dielectric film on top of the ridge is about 2.0 μm. When the resist coating is applied by a normal spin coating process, the resulting variations of the resist layer thickness within the wafer will fall within 10%. From the above description, it is presumed that the length of the side face of the dielectric film 21A exposed by the after-exposure development is within 0.2 μm.

Next, as shown in FIG. 4F, using the resist layer 23 as an example of the resist pattern as an etching mask, the dielectric film 21A exposed from the resist layer 23 is removed by etching with buffered hydrofluoric acid. In this process, in the region having the minimum resist layer thickness on the p-GaAs contact layer 6, the etching of the dielectric film 21A progresses not only from above but also from sideways. More specifically, in etching removal of the 0.2 μm dielectric film 21A on the p-GaAs contact layer 6, the dielectric film 21A present in side portions of the p-GaAs contact layer 6 is also subjected to the 0.2 μm etching. In this case, since the layer thickness of the p-GaAs contact layer 6 is as thick as 0.4 μm, the etching of the dielectric film placed in side portions of the p-GaAs contact layer 6 is stopped within the side faces of the p-GaAs contact layer 6, as shown in FIG. 4G. That is, the side faces of the p-(Al_{0.7}Ga_{0.3})_{0.5}In_{0.5}P third cladding layer 14 are not exposed. As a result, the upper-side (the side farther from the n-GaAs substrate 1A) inner edges of the edge portions 22 of the dielectric film 21 are never located on the p-(Al_{0.7}Ga_{0.3})_{0.5}In_{0.5}P third cladding layer 14. Accordingly, the top face of the p-GaAs contact layer 6 and upper portions of the side faces of the p-GaAs contact layer 6 only are exposed from the resist layer 23.

Next, after the removal of the resist layer 23, a p-side electrode 31 composed of a Ti film, a Pt film and an Au film is formed on the p-GaAs contact layer 6 and the dielectric film 21, as shown in FIG. 4H. The p-side electrode 31 is in contact with the entirety of the top face of the p-GaAs contact layer 6 and only upper portions of the side faces of the p-GaAs contact layer 6 with respect to the ridge portion 11. Accordingly, the electric current from the p-side electrode 31 is injected into the ridge portion 11 through the top face and side faces of the p-GaAs contact layer 6.

Next, the bottom face of the n-GaAs substrate 1A is polished, whereby an n-GaAs substrate 1 having a wafer thickness (50 to 130 μm thick) is obtained, which thickness is suitable for dividing the wafer into semiconductor lasers.

Finally, an n-side electrode 34 is formed on the bottom face of the n-GaAs substrate 1, followed by alloying of the p-side electrode 31 and the n-side electrode 34. As a result, a multilayered structure of a ridge waveguide type semiconductor laser wafer is completed.

In the manufacture of the semiconductor laser device including the ridge portion 11, the terrace portions 12, and the recess portions 13, regions where the side faces of the dielectric film 21A are exposed would take place due to variations of the resist layer thickness (variations within a range of 0 μm to about 0.2 μm) in the photolithography process for the removal of the dielectric film. However, since the layer thickness of the p-GaAs contact layer 6 is set 0.2 μm or more larger than the thickness of the dielectric film 21A deposited on the p-GaAs contact layer 6, it is implementable, even with the etching of the dielectric film 21A in the above-described regions, to prevent the side faces of the p-(Al_{0.7}Ga_{0.3})_{0.5}In_{0.5}P third cladding layer 14 from being exposed while fully removing the dielectric film 21A on top of the p-GaAs contact layer 6. It follows that the boundaries between the edge portions 22 of the dielectric film 21 and the p-side electrode 31 are formed on the side faces of the p-GaAs contact layer 6 with high controllability.

Also, since the side faces of the p-(Al_{0.7}Ga_{0.3})_{0.5}In_{0.5}P third cladding layer 14 do not fail to be covered with the dielectric film 21, the transverse mode controllability is improved and moreover Au diffusion into the p-(Al_{0.7}Ga_{0.3})_{0.5}In_{0.5}P third cladding layer 14 is prevented by the dielectric film 21 so that the reliability is improved.

Further, by the presence of the terrace portions 12 on both sides of the ridge portion 11 with the recess portions 13 sandwiched therebetween, the ridge portion 11 is prevented from being damaged during the manufacturing process.

Furthermore, the presence of the terrace portions 12 on both sides of the ridge portion 11 with the recess portions 13 sandwiched therebetween provides an advantage that deteriorations of the laser device due to concentration of loads to the ridge portion during the mounting operation are prevented even in the case where a so-called junction down mounting is employed for improvement of heat dissipation of the semiconductor laser device.

FIGS. 4I to 4K show enlarged manufacturing process diagrams of photolithography and etching steps for the removal of the dielectric film on the contact layer.

In FIG. 4I, the dielectric film 21A on top of the p-GaAs contact layer 6 is set to a film thickness of 0.05 μm, and the p-GaAs contact layer 6A is set 0.2 μm or more thicker than that film thickness. More specifically, the layer thickness of the p-GaAs contact layer 6A is set to 0.3 μm.

In the case where the film thickness of the dielectric film 21A on the p-GaAs contact layer 6 is not more than 0.2 μm like this, if the variance of the resist layer thickness is 0.2 μm, as shown in FIG. 4I, then there can be obtained remarkable effects, even with etching performed in the regions of the minimum resist layer thickness as shown in FIG. 4J, that the dielectric film 21A on top of the p-GaAs contact layer 6 is fully removed, as shown in FIG. 4H, and that the side faces of the p-(Al_{0.7}Ga_{0.3})_{0.5}In_{0.5}P third cladding layer 14 is reliably prevented from being exposed.

In the structure of FIG. 3, the boundaries between the edge portions 22 of the dielectric film 21 and the p-side electrode 31 are located so as to be in contact with central portions of the side faces of the p-GaAs contact layer 6. However, the boundaries may be in contact with, for example, upper ends of the side faces of the p-GaAs contact layer 6, or with lower ends of the side faces of the p-GaAs contact layer 6. That is, the p-GaAs contact layer 6-side edges of the boundaries have only to be placed between a plane containing the top face of the p-GaAs contact layer 6 and a plane containing the bottom face of the p-GaAs contact layer 6.

### THIRD EMBODIMENT

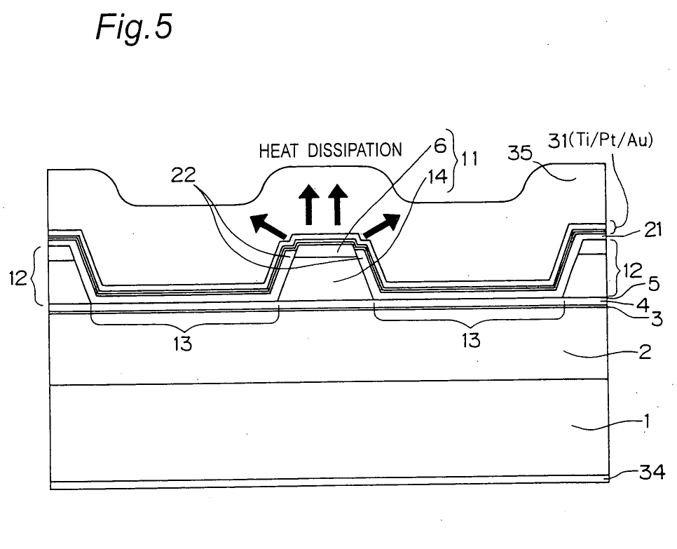

FIG. 5 shows a schematic sectional view of a semiconductor laser device according to a third embodiment of the present invention. In FIG. 5, the same constituent parts as those of the second embodiment shown in FIG. 3 are designated by the same reference numerals as those of FIG. 3, and their description is omitted.

This semiconductor laser device differs from the semiconductor laser device of the second embodiment in that a plating electrode 35 as an example of the Au plating film is formed on the p-side electrode 31.

The manufacture of the semiconductor laser device of this embodiment produces the same effects and advantages as with the semiconductor laser device of the second embodiment. Moreover, since the plating electrode 35 is formed on the p-side electrode 31, good heat dissipation is obtained so that the high-temperature, high-output operation has an improved reliability.

Also, not the dielectric film 21, which is poor at thermal conductivity, but the plating electrode 35 is in contact with the upper portions of the side faces of the p-GaAs contact layer 6. Therefore, the heat dissipation of the laser device is further improved.

In the manufacturing method of the semiconductor laser device of this embodiment, layers of from the n-(Al_{0.7}Ga_{0.3)}_{0.5}In_{0.5}P first cladding layer 2 to the p-side electrode 31 are formed on the n-GaAs substrate 1A by performing same steps as in the second embodiment (see FIGS. 4A to 4H).

Next, after a resist pattern (not shown) is formed on the p-side electrode 31 by the photolithographic technique, electric power is fed to the p-side electrode 31 exposed at wafer ends, by which electrolytic Au plating is performed. As a result of this, a plating electrode 35 made of Au and having a film thickness of 1.5 to 5.0 μm is formed on the p-side electrode 31.

The resist pattern covers dividing portions of the semiconductor layer wafer for division into semiconductor laser devices. Therefore, since the plating electrode 35 is not formed on the dividing portions, the division of the semiconductor layer wafer into semiconductor laser devices is easily achieved by removing the resist pattern.

Next, the bottom face of the n-GaAs substrate 1A is polished so as to obtain an n-GaAs substrate 1 having a wafer thickness (50 to 130 μm thick) suitable for division of the wafer into semiconductor laser devices.

Finally, an n-side electrode 34 is formed on the bottom face of the n-GaAs substrate 1, followed by alloying of the p-side electrode 31 and the n-side electrode 34. As a result, a multilayered structure of a ridge waveguide type semiconductor laser wafer is completed.

The third embodiment has been shown on the case of a full-surface electrode in which the p-side electrode covers the dielectric film as well. In the case of a striped electrode in which the p-side electrode is limited to a place on the contact layer in upper part of the ridge, it is also possible that after the formation of the striped p-side electrode, a plating base electrode is formed all over the wafer and Au plating is performed.

In the structure of FIG. 5, the boundaries between the edge portions 22 of the dielectric film 21 and the p-side electrode 31 are located so as to be in contact with central portions of the side faces of the p-GaAs contact layer 6. However, the boundaries may be in contact with, for example, upper ends of the side faces of the p-GaAs contact layer 6, or with lower ends of the side faces of the p-GaAs contact layer 6. That is, the p-GaAs contact layer 6-side edges of the boundaries have only to be placed between a plane containing the top face of the p-GaAs contact layer 6 and a plane containing the bottom face of the p-GaAs contact layer 6.

### FOURTH EMBODIMENT

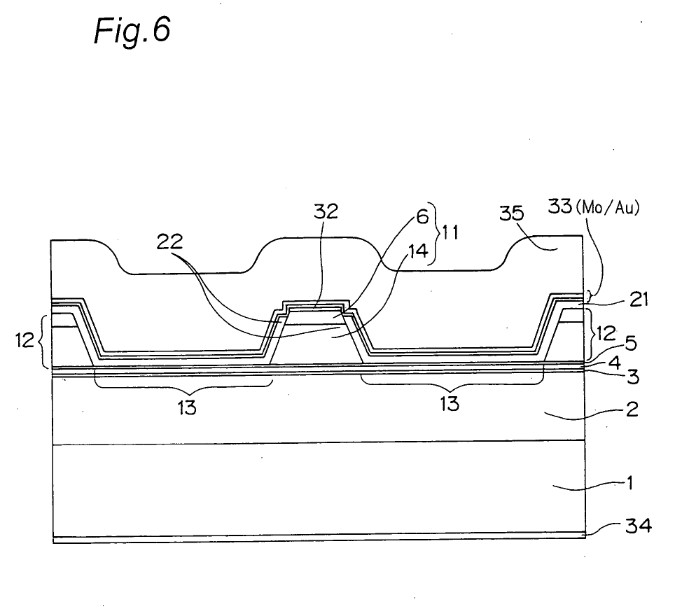

FIG. 6 shows a schematic sectional view of a semiconductor laser device according to a fourth embodiment of the present invention. In FIG. 6, the same constituent parts as those of the third embodiment shown in FIG. 5 are designated by the same reference numerals as those of FIG. 5, and their description is omitted.

This semiconductor laser device differs from the semiconductor laser device of the third embodiment in that a striped p-side electrode 32 as an example of the on-ridge electrode is formed instead of the p-side electrode 31 and that a plating base electrode 33 is formed under the plating electrode 35. The p-side electrode 32 and the plating base electrode 33 constitute an example of the on-ridge electrode.

The semiconductor laser device of this embodiment produces the same effects as with the semiconductor laser device of the third embodiment. Moreover, since the plating base electrode 33 is formed under the plating electrode 35, it is implementable, even with the formation of the plating electrode 35 made of Au, to prevent the Au of the plating electrode 35 from being diffused to the side faces of the p-GaAs contact layer 6.

In the manufacturing process of the semiconductor laser device of this embodiment, the striped p-side electrode is formed on the contact layer by removal of p-side electrode material on the other portions by the liftoff of the resist pattern in the photolithographic process performed for removal of those parts of the dielectric film that are in contact with the top face and upper portions of the side faces of the contact layer being an upper portion of the ridge portion. Then, a plating base electrode including a barrier metal that prevents Au diffusion is formed, and a plating electrode is formed on the plating base electrode.

The manufacturing method of the semiconductor laser device will be explained in more detail below.

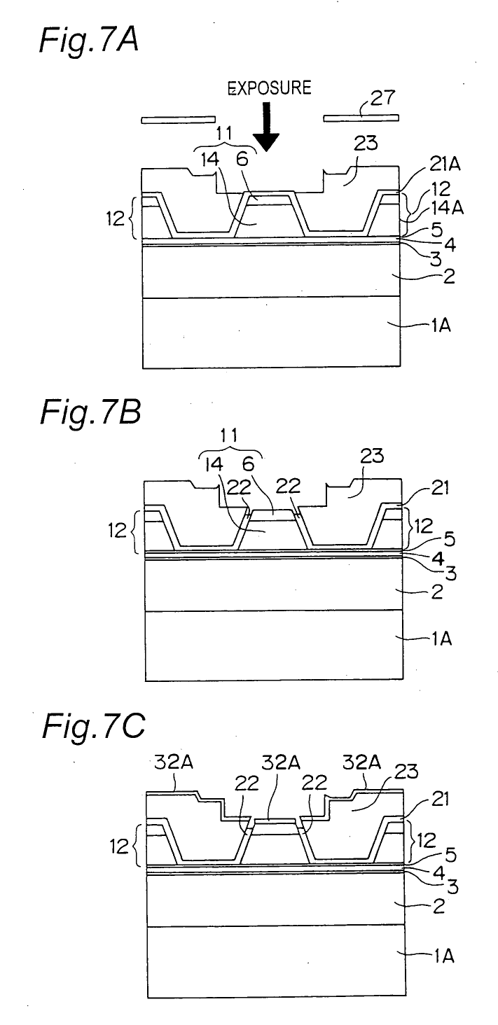

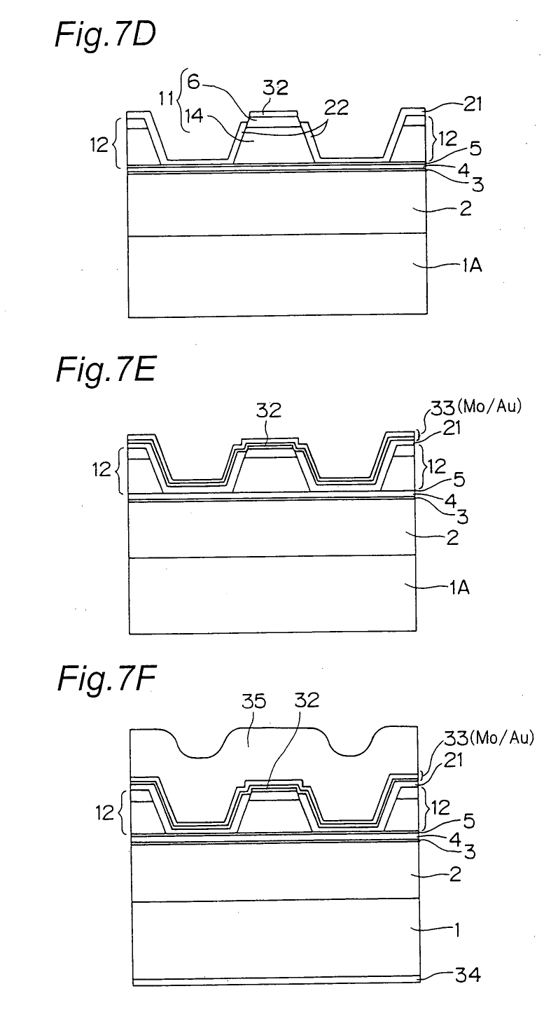

FIGS. 7A to 7F show manufacturing process diagrams of the semiconductor laser device of this embodiment.

In the manufacturing method of the semiconductor laser device of this embodiment, as shown in FIG. 7A, the layers of from the n-(Al_{0.7}Ga_{0.3})_{0.5}In_{0.5}P first cladding layer 2 to the dielectric film 21A are formed on the n-GaAs substrate 1A by performing the same steps as in the second embodiment (see FIGS. 4A to 4H), and thereafter the resist layer 23 is formed by performing an exposure step and a development step. The top face of the dielectric film 21A and the upper portions of the side faces of the dielectric film 21A are exposed from the resist layer 23. Although not shown, viewing the entire wafer, there may be regions where only the top face of the dielectric film 21A is exposed.

Next, using the resist layer 23 as an etching mask, the dielectric film 21A exposed from the resist layer 23 is removed by etching with buffered hydrofluoric acid, as a result of which a dielectric film having edges 22 is formed. In this process, the etching of the dielectric film 21A progresses not only from above but also from sideways. More specifically, in etching removal of the 0.2 μm dielectric film 21A on the p-GaAs contact layer 6, the dielectric film 21A present in side portions of the p-GaAs contact layer 6 is also subjected to the 0.2 μm etching. At this time, since the layer thickness of the p-GaAs contact layer 6 is as thick as 0.4 μm, the etching of the dielectric film placed at side portions of the p-GaAs contact layer 6 is stopped within the side faces of the p-GaAs contact layer 6, as shown in FIG. 7B. That is, the side faces of the p-(Al_{0.7}Ga_{0.3})_{0.5}In_{0.5}P third cladding layer 14 are not exposed. As a result, the upper-side (the side farther from the n-GaAs substrate 1A) inner edges of the edge portions 22 of the dielectric film 21 are never located on the p-(Al_{0.7}Ga_{0.3})_{0.5}In_{0.5}P third cladding layer 14. Accordingly, the top face of the p-GaAs contact layer 6 and upper portions of the side faces of the p-GaAs contact layer 6 only are exposed from the resist layer 23.

The reason why the removal of the dielectric film 21A on the p-GaAs contact layer 6 is done not by dry etching but by wet etching is that dry etching such as RIE (Reactive Ion Etching) causes the resist layer covering the dielectric film 21A to be altered in properties, so that the resist layer 23 becomes difficult to remove after the removal of the dielectric film 21A on the p-GaAs contact layer 6. Even if the resist layer 23 is removed, resist residua are likely to arise. In particular, with the use of organic solvents or resist stripping agents, the resist removal becomes hard to achieve, so that performing the electrode liftoff by using the resist layer 23 becomes hard to achieve.

Next, as shown in FIG. 7C, an AuZn film 32A having a film thickness of 400 to 3000 Å is deposited all over the wafer in which the resist layer 23 is left.

Next, the AuZn film 32A on the resist layer 23 is removed by liftoff process, and the striped p-side electrode 32 made of AuZn is formed on the p-GaAs contact layer 6 as shown in FIG. 7D.

When the AuZn film 32A is deposited, the AuZn film 32A may not be deposited at upper portions of the side faces of the p-GaAs contact layer 6 due to the shielding of the resist layer 23. In this case, removing the AuZn film 32A on the resist layer 23 by liftoff process causes the upper portions of the side faces of the p-GaAs contact layer 6 to be exposed. Therefore, in order that the upper portions of the side faces of the p-GaAs contact layer 6, even if exposed, are prevented from intrusion of Au plating solution and/or diffusion of Au, an electrode including a barrier metal for prevention of the intrusion of the Au plating solution and diffusion of Au is formed in the subsequent step.

Next, Mo (molybdenum) is deposited to a film thickness of 300 to 2000 Å on the entire surface of the wafer as shown in FIG. 7E, and thereafter Au is further deposited to a film thickness of 500 to 3000 Å. As a result of this, a plating base electrode 33 made of the Mo film and the Au film is formed. This plating base electrode 33 is an example of the metal film.

The plating base electrode 33 serves not only as a base of plating but also for preventing the outward diffusion of Ga and diffusion of Au into the quantum well active layer 3 with the Mo film used as a barrier metal.

Next, after a resist pattern (not shown) is formed on the plating base electrode 33 by the photolithography technique, electric power is fed to the plating base electrode 33 exposed at wafer ends, by which electrolytic Au plating is performed. As a result of this, a plating electrode 35 made of Au and having a film thickness of 1.5 to 5.0 μm is easily formed on the plating base electrode 33 as shown in FIG. 7F.

The resist pattern covers dividing portions of the semiconductor layer wafer for division into semiconductor laser devices. Therefore, the plating electrode 35 is not formed on the dividing portions, and the division of the semiconductor layer wafer into semiconductor laser devices is easily achieved by removing the resist pattern.

Next, the bottom face of the n-GaAs substrate 1A is polished so as to obtain an n-GaAs substrate 1 having a wafer thickness (50 to 130 μm thick) suitable for division of the wafer into semiconductor laser devices.

Finally, an n-side electrode 34 is formed on the bottom face of the n-GaAs substrate 1, followed by alloying of the p-side electrode 32 and the n-side electrode 34. As a result, a multilayered structure of a ridge waveguide type semiconductor laser wafer is completed.

As shown above, since the liftoff of the AuZn film 32A on the resist layer 23 is performed by using the resist layer 23 that has been used for the removal of the dielectric film 21A on the p-GaAs contact layer 6, no resist pattern for the formation of the striped p-side electrode 32 needs to be formed independently of the resist layer 23. That is, one resist pattern will do for both the removal of the dielectric film 21A on the p-GaAs contact layer 6 and the formation of the striped p-side electrode 32. Accordingly, misalignment between the step of removing the dielectric film 21A on the p-GaAs contact layer 6 and the step of forming the striped p-side electrode 32 is prevented from occurrence.

Since one resist pattern will do for both the removal of the dielectric film 21A on the p-GaAs contact layer 6 and the formation of the striped p-side electrode 32, the manufacture of the semiconductor laser device can be simplified with the number of manufacturing steps cut down.

Further, since the plating base electrode 33 made of a Mo film and an Au film is formed after the formation of the p-side electrode 32, intrusion of the Au plating solution into the side faces of the p-GaAs contact layer 6 or diffusion of Au into the side faces of the p-GaAs contact layer 6 can reliably be prevented even though the plating electrode 35 made of Au is formed.

Although the plating base electrode 33 made of Mo film and Au film is formed in the fourth embodiment, a plating base electrode having an electrode material (Ti, etc.) of high adhesion to the dielectric film and a barrier metal (Ti, Pt, etc.) for prevention of Au diffusion may also be formed instead of the plating base electrode 33. However, in that case, the topmost surface (plating side surface) of the plating base electrode should be made of Au.

In the structure of FIG. 6, the boundaries between the edge portions 22 of the dielectric film 21 and the plating base electrode 33 are located so as to be in contact with central portions of the side faces of the p-GaAs contact layer 6. However, the boundaries may be in contact with, for example, upper ends of the side faces of the p-GaAs contact layer 6, or with lower ends of the side faces of the p-GaAs contact layer 6. That is, the p-GaAs contact layer 6-side edges of the boundaries have only to be placed between a plane containing the top face of the p-GaAs contact layer 6 and a plane containing the bottom face of the p-GaAs contact layer 6.

Although the p-side electrode 32 is in contact with the top face of the p-GaAs contact layer 6 and not in contact with the side faces of the p-GaAs contact layer 6 in the structure of FIG. 6, the p-side electrode 32 may also be in contact with both the top face and the side faces of the p-GaAs contact layer 6.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor laser device comprising:
compound semiconductor layers formed on a substrate;
a striped ridge portion which is formed on the compound semiconductor layer and which includes a plurality of layers, a topmost layer thereof being a contact layer;
a dielectric film formed on both sides of the ridge portion; and
an on-ridge electrode which is in contact with a top face and side faces of the contact layer, wherein
side faces of the ridge portion except the contact layer which is in contact with the on-ridge electrode are covered with the dielectric film, and
the contact layer has a layer thickness larger than a film thickness of a portion of the dielectric film that is roughly parallel to the substrate.

2. The semiconductor laser device as claimed in claim 1, further comprising
terrace portions formed on both sides of the ridge portion, with a recess portion sandwiched between the ridge portion and each terrace portion, wherein
the recess portions and the terrace portions are buried in the dielectric film.

3. The semiconductor laser device as claimed in claim 1, further comprising
an Au plating film which is formed over the ridge portion and which contains Au.

4. The semiconductor laser device as claimed in claim 3, wherein
the on-ridge electrode comprises a metal film which is formed between the Au plating film and the ridge portion and which includes a barrier metal that prevents diffusion of Au.

5. A method for manufacturing a semiconductor laser device comprising:
a first step of forming compound semiconductor layers on a substrate;
a second step of forming on the compound semiconductor layers a striped ridge portion which includes a plurality of layers, a topmost layer thereof being a contact layer;
a third step of forming a dielectric film on the compound semiconductor layers and the ridge portion;
a fourth step of forming a resist pattern on the dielectric film such that portions of the dielectric film present on a top face and side faces of the contact layer are exposed;
a fifth step of removing the dielectric film exposed from the resist pattern by etching such that the top face and side faces of the contact layer are exposed; and
a sixth step of forming an on-ridge electrode which is in contact with the top face and side faces of the contact layer, wherein
in the third step, the dielectric film is formed such that a layer thickness of the contact layer is larger than a film thickness of the dielectric film present on the contact layer.

6. The method for manufacturing the semiconductor laser device as claimed in claim 5, wherein
the etching is wet etching.

7. The method for manufacturing the semiconductor laser device as claimed in claim 5, wherein
the on-ridge electrode is formed by liftoff process using the resist pattern.

8. The method for manufacturing the semiconductor laser device as claimed in claim 5, wherein
in the third step, the dielectric film is formed such that the layer thickness of the contact layer becomes larger than a thickness resulting from adding 0.2 μm to the film thickness of the dielectric film present on the contact layer.

9. The method for manufacturing the semiconductor laser device as claimed in claim 5, wherein
the sixth step includes a seventh step of forming, over the ridge portion, a metal film containing a barrier metal for prevention of Au diffusion; and
the method further comprises an eighth step of forming over the metal film an Au plating film containing Au.
